(19) United States
(12) Patent Application Publication
(10) Pub. No.: US 2025/0103769 A1
(43) Pub. Date: Mar. 27, 2025

(54) MODELLING METHOD AND SYSTEM FOR A GLASS STRUCTURE

(71) Applicant: AGC GLASS EUROPE, Louvain-la-Neuve (BE)

(72) Inventors: Mohammad SHAYESTEH, Gosselies (BE); Louis DELLIEU, Waret-La-Chaussée (BE); Antony ESCUDIE, Gosselies (BE); Grégoire BESSE, Gosselies (BE)

(73) Assignee: AGC GLASS EUROPE, Louvain-la-Neuve (BE)

(21) Appl. No.: 18/832,590

(22) PCT Filed: Feb. 20, 2023
(86) PCT No.: PCT/EP2023/054237

§ 371 Date: Jul. 24, 2024

(30) Foreign Application Priority Data
Feb. 18, 2022 (EP) 22157594.7

(51) Int. Cl. G06F 30/20; G06F 30/13

(52) U.S. Cl. CPC G06F 30/20; G06F 30/13

(57) ABSTRACT

A method is provided for modelling irradiance levels in a solar light type glass greenhouse, the greenhouse including a plurality of glass panels having at least one glass panel type, and the greenhouse having an intended geographical location and intended orientation. The method includes: providing a three-dimensional structural model of the greenhouse, the structural model containing: modelled glass panels, modelled structural components, a modelled intended geographical location, and a modelled intended orientation; determining at least a first set of characteristics for the modelled glass panels and a second set of characteristics for the modelled structural components; providing a set of environmental data; using a rendering component to determine an irradiance map of the greenhouse based on the 3-dimensional structural model, the at least one first and second sets of characteristics, and the set of environmental data; and optimizing the irradiance maps based on a set of optimization criteria.

### TECHNICAL FIELD

The present disclosure relates to the field of modelling light propagation in a structure. Such a system can be used for example to model light propagation and irradiance in a glass structure, such as a greenhouse.

### BACKGROUND

Greenhouses are commonly used in many parts of the world to increase productivity of crop yields or to create a controlled environment in which crops can be grown that would otherwise not be growable in that part of the world.

The structure, dimensions and choice of materials used in the construction of a greenhouse is typically to enable the crop yield to be maximized. In particular, a greenhouse may be constructed to maximizing the amount of useful light that falls on the crops grown therein. The amount of light that falls on crops in a greenhouse is directly linked to the amount of photosynthesis and other growing processes in the crops and, therefore, it is beneficial to maximize the amount of useful light that hits the crops. This is particularly important for latitudes (e.g., Northern Europe) where light is scarce for a significant part of the year. It may also be important in latitudes wherein too much light may be prevalent for a certain type of crop or plant to be grown.

However, due to the climate diversity of the various regions of the world, a solution that is used in one part of the world may not be suitable for another part of the world. For example, structures or cover material choices that are suitable for northern Europe may not be optimized for other parts of the world.

Therefore, there is a need to adapt material choices for a greenhouse to take into account the geographical location and orientation of the greenhouse. The geographical location of a greenhouse also affects the weather patterns that the greenhouse is exposed to, which in turn affects the light distribution in the light house. As an example, the location of a greenhouse determines the amount and angles of natural light that hits the greenhouse.

Further, there is a need to take into account the structure of a particular greenhouse, including the facilities and internal structures thereof (e.g., screens, sensor installations, artificial lighting). Any such structures may impact the amount and distribution of light inside the greenhouse. For example, a light fixture may cast shadows on the crops.

Given the requirements for a greenhouse, such as those described above, design and manufacture of a greenhouse is time consuming and resource-intensive. For example, the choice of panel types and materials have a direct effect on the productivity of a greenhouse. If the wrong types of panels are fitted in a greenhouse, the crop yield may be negatively impact. In extreme circumstances, it may be impossible to grow certain crops or plants in a greenhouse if it is poorly designed. Further, the transparent panels, which are typically made of a glass material, can be costly and time consuming to construct and prepare.

Due to the high cost of glass materials, it is highly undesirable, or even impossible, to replace or retrofit panels on a greenhouse that has been poorly or inaccurately designed and manufactured.

There is therefore a need to be able to accurately predict the properties and productivity of a greenhouse over a significant period of time.

### SUMMARY

The present disclosure concerns a method for modelling irradiance levels in a solar light type glass greenhouse, the greenhouse comprising a plurality of glass panels having at least one glass panel type, and the greenhouse having an intended geographical location and intended orientation, the method comprising:
providing a three-dimensional structural model of the greenhouse, the structural model comprising: a plurality of modelled glass panels, a plurality of modelled structural components, a modelled intended geographical location, and a modelled intended orientation;
determining at least a first set of characteristics for the plurality of modelled glass panels and at least a second set of characteristics for the plurality of modelled structural components;
providing a set of environmental data, the environmental data being associated with the intended geographical location and orientation;
using a rendering component to determine an irradiance map of the greenhouse based on the 3-dimensional structural model, the at least one first and second sets of characteristics, and the set of environmental data; and
optimizing the irradiance maps based on a set of optimization criteria.

Additional features of the method are provided in the dependent claims of the present disclosure.

The present disclosure further concerns a method for operating a greenhouse control unit in a greenhouse, the greenhouse comprising one or more climate control units operable to control one of a plurality of environment parameters and one or more climate sensors, the method comprising: receiving a predicted climate profile; generating a climate control profile based on the predicted climate profile, the climate control profile comprising climate control data for the one or more climate control units; and transmitting the climate control data to the one or more climate control units.

The present disclosure further concerns a computer program comprising instructions which, when the program is executed by a computer, cause the computer to carry out the method as set out above.

The present disclosure additionally concerns a computer readable medium including program instructions which, when executed by a computer, cause the computer to carry out the method as set out above.

Further, the present disclosure concerns a computer system, the computer system comprising a processing unit, wherein the computer system is operable to carry out the method as set out above.

### BRIEF DESCRIPTION OF THE DRAWINGS

Other features, purposes and advantages of the invention will become more explicit by means of reading the detailed statement of the non-restrictive embodiments made with reference to the accompanying drawings.

FIG. 1 illustrates schematically a solar light type glass greenhouse.

FIG. 2 shows schematically a number of exemplary glass panels for use in a greenhouse.

FIG. 3 shows a method for modelling irradiance levels in a solar light type glass greenhouse in accordance with an aspect of the invention.

FIG. 4 illustrates schematically the method of FIG. 3.

FIG. 5 shows an exemplary optimization step in accordance with an aspect of the invention.

FIG. 6 shows schematically the method of FIG. 5.

FIG. 7 shows a step of providing a set of environmental data in accordance with an aspect of the invention.

FIG. 8 illustrates schematically the method of FIG. 7.

FIG. 9 illustrates a step of using a rendering component to determine an irradiance map of the greenhouse in accordance with an aspect of the invention.

FIG. 10 shows schematically the method of FIG. 9.

FIG. 11 shows a step of deriving a spectral response of the modelled crop element in accordance with an aspect of the invention.

FIG. 12 illustrates schematically the method of FIG. 11.

FIG. 13 shows a method for operating a greenhouse control unit in accordance with an aspect of the invention.

FIG. 14 illustrates schematically the method of FIG. 13.

### DETAILED DESCRIPTION

Before describing the exemplary embodiments of the invention, it may be illustrative to describe an exemplary scenario in which the present invention may be utilized.

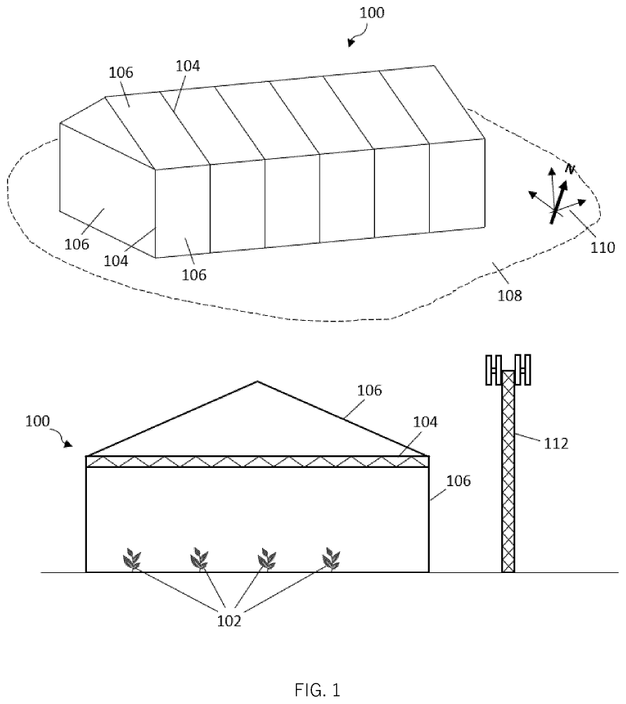

FIG. 1 illustrates schematically a solar light type glass greenhouse 100 in which crops 102 are cultivated. The greenhouse has a plurality of structural components 104 and a plurality of glass panels 106.

The greenhouse is located in a geographical location 108 and with a particular orientation 110. The geographical location will affect the light propagating into the greenhouse. In particular, geographical location determines the position of the sun in the sky, which determines the angle of light entering the greenhouse, and the length of the day, which affects the amount of light and angles of light entering the greenhouse. For example, a greenhouse located at higher longitudes (e.g., in northern Europe or North America) will receive different amounts of light to a greenhouse located near the equator.

In some instances, geographical structures 112, whether natural or artificial, in the vicinity of the greenhouse may affect the properties of the light in the greenhouse. Most greenhouses are positioned in flat locations that are free of light-obstructing geographical structures (such as hills or tall structures). However, in some instances, this may not always be possible, and it may be necessary to include one or more neighboring geographical structures in the model.

The orientation of the greenhouse 100 affects the distribution of light within the greenhouse. Structural components 104 of the greenhouse affect the propagation of light within the greenhouse (e.g., by obstructing certain light beams, reflecting light beams, diffusing light beams or otherwise modifying light propagation). The arrangement of the structural components of the greenhouse will, therefore, influence the light levels in specific parts of the greenhouse. The orientation 110 of the greenhouse influences the number and arrangement of structural components positioned in the path of the light from the sun. It is, therefore, advantageous to ensure that the greenhouse is oriented such that the amount of input light is maximized.

As will be appreciated, the aim of a greenhouse is essentially to maximize useful radiation levels on the crops or plants therein. Another aim is to ensure that other environmental factors, notably temperature, is as close to ideal for the crops or plants at all times. It is therefore advantageous to ensure that the light levels or irradiance of any given location inside the greenhouse is as close to uniform as possible. Any differences in irradiance may result in differential growth of the crops, which in turn may lead to a reduced output.

Different types of plants or crops require different levels of light in order to grow optimally. In some cases, non-optimal levels of light may be detrimental to plant or crop growth, and may even be detrimental to plant or crop health. It is therefore advantageous if light levels can be optimized in order to ensure such growth conditions.

Light levels are dependent on the geographical location 108 of the greenhouse, but may, of course, be modified by suitable choice of glass panels. Glass panels to be used in a greenhouse may have any suitable optical properties. A number of exemplary glass panels will be discussed in more detail below.

As discussed above, it is therefore necessary to model or predict the performance or productivity of a greenhouse, preferably during the design phase. However, modelling complex structures and environments such as a greenhouse may involve considerable computational resources and make take a significant amount of time. Known modelling solutions therefore generally rely on generalizations and simplifications in order to reduce the computational burden and the time taken to achieve a result. For example, known solutions may use annual average light levels from the sun. Whilst this reduces the computational complexity, it does accurately model the variance in light levels that may occur within a single day, but which may have significant impact on the productivity of a greenhouse.

Further, known solutions may simplify computations by using an average irradiance level for the entirety of a greenhouse, i.e., by assuming that the irradiance level in the greenhouse is uniform. However, the amount of light that falls upon various sections of a greenhouse may vary, for example due to the internal structures in the greenhouse or due to external structures adjacent to the greenhouse. Averaging over the entirety of a greenhouse may significantly reduce the accuracy of the modelling.

Yet further, known solutions do not generally take into account the orientation of the greenhouse and the 3D model of the greenhouse at the same time, which may impact the distribution of light in the greenhouse especially closer to the outer side walls and sectional walls inside the greenhouse.

As a result, by using known methods it is not possible to provide accurate predictions of the conditions inside a greenhouse, nor is it possible to predict the resulting productivity of a greenhouse. This, in turn, leads to a generally lower than ideal productivity since the greenhouse is not optimized for its function.

This can be exemplified by the following illustrative examples. By using an average light level for an entire greenhouse, the amount of energy consumed by the greenhouse may be significantly increased. If, for example, a portion of the greenhouse is in shade for a significant part of the year, it may be necessary to use artificial light in order to ensure that the plants in this portion of the greenhouse are productive. However, by using an average light level only, all light fixtures in the greenhouse will be turned on, which may waste energy in some situations (since they are not needed in the remaining portions of the greenhouse). In another illustrative example, using an average light level may lead to a certain percentage of crops or plants being lost due to adverse conditions (e.g., in situations where light levels in parts of the greenhouse are too high or too low for a particular crop to grow).

Crops or plants can under certain circumstances be negatively influenced by unsuitable conditions that occur only for short amounts of time. For example, certain crops may be damaged by overexposure to light even for an hour.

As described above, there is therefore a need for predicting the behaviour of a greenhouse, and in particular predicting the irradiance (and/or other growth-relevant factors or conditions) of crops or plants within a greenhouse over a specific period of time (e.g., a growing season). Further, there is a need for predicting the conditions within a greenhouse for an extended period (e.g., several years or decades) but with a high granularity (so as to avoid reduction in productivity or damage to crops as described above).

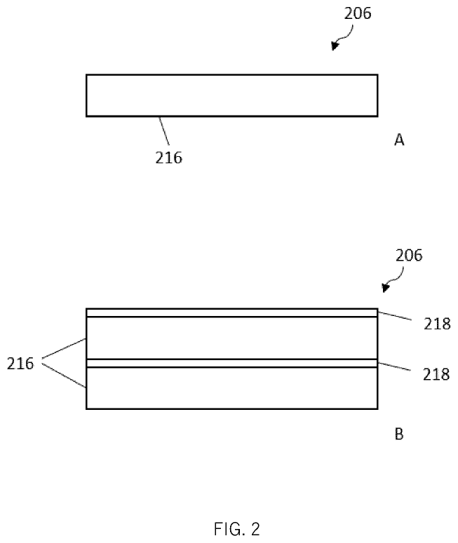

A number of exemplary glass panels 206 that may be used in a greenhouse such as the one described with reference to FIG. 1 above will now be discussed with reference to FIG. 2. For ease of comparison with FIG. 1, elements of FIG. 2 similar to corresponding elements of FIG. 1 are labelled with reference signs similar to those used in the preceding Figures, but with prefix “2”.

Specifically with respect to cultivation of crops, it is useful to characterize performance of a glass material by the photosynthetic active radiation (PAR) transmitted by the glass material as well as hemispherical light transmission described in NEN2675+C1: 2018.

In some examples, as illustrated in FIG. 2A, a glass panel 206 comprises a single glass element 216 or sheet. The glass element may be comprised of any suitable glass material with a suitable set of optical properties. It will be appreciated that the specific choice of glass material is dependent on a number of factors, design choices and requirements which go beyond the present disclosure.

In other examples, an illustrative one of which is shown in FIG. 2B, a glass panel 206 comprises a plurality of glass elements 216.

Additionally, in the present example, the glass panel comprises two optical layers 218. It will be appreciated, of course, that any suitable or desired number of optical layers may be utilized, and that the ones in the present example are purely for illustrative purposes. Optical coatings are commonly used to modify the optical properties of the light or radiation passing through. For example, optical coatings are used to filter or remove certain wavelengths by reflecting these. Optical coatings can also, for example, be used to reduce overall light intensities in a greenhouse.

By suitable choice of the glass elements and any optical coatings used in a glass panel, it is possible to control the properties of the light that enters the greenhouse. For example, glass elements and/or optical coatings can be chosen so as to maximize the amount of PAR that is transmitted and to minimize any potentially harmful light or radiation. Additionally or alternatively, the glass elements and/or optical coatings are chosen so as to modify the spectral content of the light entering the greenhouse so as to be optimized for a particular type of plant or crop. This will be discussed in more detail in the following.

It will be appreciated that the above glass panels are described for exemplary and explanatory purposes only. It will further be appreciated that other glass panels, and combinations thereof, are easily envisaged within the scope of the present disclosure.

The glass panel can be a single glass sheet or a multi-glazed window. The multi-glazed window is made of multiple glass sheets, and at least a first and a second glass sheets separated by at least one interlayer. The glass sheets therefore can be separated by an interlayer which is a space filled with gas and/or by at least one polymeric interlayer.

In some embodiments, the multi-glazed window can comprise at least two glass sheets separated by a spacer allowing to create a space filled by a gas like Argon to improve the thermal isolation of the multi-glazed window or vacuum, creating an insulating multi-glazed window. The invention is not limited to apparatus for use on multi-glazed window having two panels. The apparatus and method of the present invention are suitable for any multi-glazed window such as vacuum, double, triple glazed windows.

In some embodiments, the panel interlayer is a thermoplastic interlayer bonding the first glass sheet and the second glass sheet together meaning that the glazing panel can be a laminated multi-glazed window such as those to reduce the noise and/or to ensure the penetration safety. The thermoplastic interlayer can be made by one or more interlayers positioned between glass sheets. The interlayers are typically polyvinyl butyral (PVB) or ethylene-vinyl acetate (EVA) for which the stiffness can be tuned. These interlayers keep the glass sheets bonded together even when broken in such a way that they prevent the glass from breaking up into large sharp pieces.

Said glass sheet can be made of glass, polycarbonate, PVC or any other material used for a window mounted on a greenhouse.

Preferably said glass sheet is made of glass. Usually, the material of the glass sheets is, for example, soda-lime silica glass, borosilicate glass, aluminosilicate glass or other materials such as thermoplastic polymers or polycarbonates which are especially known for horticulture applications. References to glass throughout this application should not be regarded as limiting.

Glass sheet can be manufactured by a known manufacturing method such as a float method, a fusion method, a redraw method, a press molding method, or a pulling method. As a manufacturing method of the multi-glazed window, from the viewpoint of productivity and cost, it is preferable to use the float method.

Each panel can be independently processed and/or colored, . . . and/or have different thickness in order to improve the light propagation and irradiance performances, aesthetic, thermal performances, safety, . . . . The thickness of a glass panel is set according to requirements of applications.

Glass panel can have any shape to fit to the opening such as a rectangular shape, in a plan view by using a known cutting method. As a method of cutting the glass panel, for example, a method in which laser light is irradiated on the surface of the glass panel to cut the glass panel, or a method in which a cutter wheel is mechanically cutting can be used. The glass panel can have any shape in order to fit with the application and the position in a greenhouse, such as gable areas and frameless ventilation windows with several holes on the glass.

Each glass sheet can be processed, i.e. annealed, tempered, . . . to respect the specifications of security requirements. The transparent dielectric slab can independently be a clear or a colored transparent dielectric panel, tinted with a specific composition or by applying an additional coating or a plastic layer for example.

Each glass sheet can be independently processed and/or colored, . . . and/or have different thickness in order to improve the light transmission and distribution, thermal or colling insulation, aesthetic, safety, . . . .

To ensure light propagation and irradiance in a glass structure, a coating/etching system can be present on one interface of a glass sheet. This coating system generally uses a metal-based layer and infrared light is highly reflected by this type of layer while the etching system distributes the incoming light evenly across the greenhouse.

Usually, the coating system is covering most of the surface of the glass sheet.

The coating system can be made of layers of different materials.

These different layers are deposited, for example, by means of vacuum deposition techniques such as magnetic field-assisted cathodic sputtering, more commonly referred to as “magnetron sputtering”. In addition to the dielectric layers, each functional layer may be protected by barrier layers or improved by deposition on a wetting layer.

Suitable coatings and glass panels ensuring the light propagation and irradiance are described in co-pending applications EP20193289.4, EP21170853.2 and EP21194145.5 which are totally incorporated by reference into the present patent application.

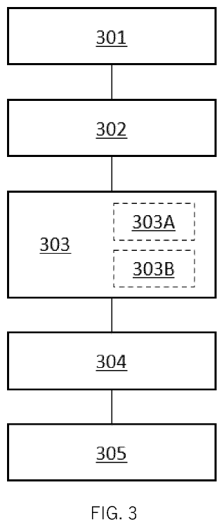

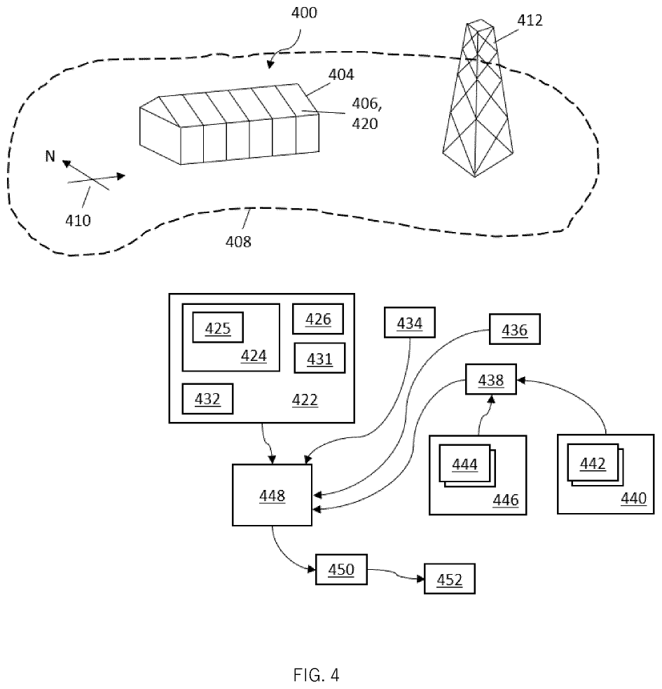

An exemplary method for modelling irradiance levels in a solar light type glass greenhouse will now be described with reference to FIG. 3 and FIG. 4. For ease of comparison with the preceding Figures, elements of FIG. 4 similar to corresponding elements of FIG. 1 are labelled with reference signs similar to those used in the preceding Figures, but with prefix “4”.

In the present example, the greenhouse 400 comprises a plurality of glass panels 406 having at least one glass panel type 420. Further, the greenhouse has an intended geographical location 408 and intended orientation 410. The greenhouse may be an existing structure, or it may be a planned structure that a user intends to construct and which may be in a suitable stage of planning.

In a first step 301, a three-dimensional structural model 422 of the greenhouse 400 is provided, the structural model comprising: a plurality of modelled glass panels 424, a plurality of modelled structural components 426, a modelled intended geographical location 428, and a modelled intended orientation 430. The first step, as well as the subsequent steps, may be carried out by a suitable computing system (not shown).

The three-dimensional structural model 422 may comprise any suitable plurality of modelled glass panels 424, each of said modelled glass panels having a suitable set of properties 425. In some examples, the greenhouse uses a single glass panel type 420. In such examples, each one of the plurality of modelled glass panels has a set of identical properties.

In some examples, the greenhouse comprises a plurality of different glass panel types 420. In such examples, the three-dimensional structural model 422 comprises a corresponding plurality of modelled glass panels 424, each of said modelled glass panels having a respective set of properties 425. Any suitable or relevant number of sets of properties may be used, including (without limitation): two, three, four, five, six, seven or eight. In some examples, the number of sets of properties 425 corresponds to the number of glass panel types 420 used in the greenhouse 400.

It will be appreciated that the three-dimensional structural model, in most examples, is intended to be substantially analogous to the greenhouse 400. In other words, when subjected to a suitably realistic modelling process, the three-dimensional structural model will yield results that are substantially analogous to measurements that could be obtained from a real-world greenhouse to which the model corresponds.

The three-dimensional structural model, in some examples, includes at least one modelled radiation source 431. The modelled radiation source provides a source of modelled radiation having a suitable set of radiation properties. In some examples, the radiation properties approximate or correspond to one or more real world measurable properties of radiation from one or more radiation sources. Examples include (without limitation): intensity, wavelength or frequency. In some examples, the modelled environmental radiation comprises a modelled radiation spectrum from the one or more modelled radiation sources. In some examples, the modelled radiation spectrum comprises a plurality of discrete radiation components, each radiation component comprising data or information associated with one or more radiation wavelengths or sub-spectra. In some examples, the modelled environmental radiation has a set of properties that mimics the properties of natural light provided by the Sun. In such examples, the modelled environmental radiation is modelled as originating from a modelled radiation source, the source having a position relative to the modelled greenhouse that corresponds to the position of the Sun. This ensures that natural light can be accurately modelled.

In an illustrative example, the Sun is modelled as a standard illuminant. In a particular example, the Sun is modelled as standard illuminant D65, as defined by the International Commission on Illumination.

In some examples, the modelled environmental radiation further takes into account the propagation of the light from the modelled radiation source through the atmosphere. This allows the inclusion of naturally occurring effects, such as diffuse atmospheric lighting, into the modelled environmental radiation. This may be implemented in a number of ways. In the present example, the modelled environmental radiation uses a Perez diffuse radiation model.

In some examples, the three-dimensional structural model comprises additional modelled radiation sources. For example, in certain examples, the additional modelled environmental radiation comprises external radiation sources that are located externally to the modelled greenhouse. This is to model any natural or artificial radiation sources positioned adjacent to or in the vicinity of the greenhouse, whose light may propagate into the interior of the lighthouse. This would be relevant, for example, in situations wherein the greenhouse is to be positioned in an urban environment in which artificial light sources are prevalent and provide a significant amount of light.

Additionally, in some examples, the modelled environmental radiation sources comprise one or more internal radiation sources that are located within the modelled greenhouse. In some situations, a greenhouse may be fitted with internal lights which can be used during night time, periods of darkness or during periods with inclement weather. Any such internal lights, and the light provided by these, can be included in the model in this manner.

In some examples, the three-dimensional structural model 422 comprises additional data 432. Any suitable additional data may be comprised in the three-dimensional structural model. In one example, the additional data comprises structural data related to a geographical structure 412 that is located externally to the greenhouse but in the vicinity thereof (such as an adjacent building). As described above, greenhouses are typically designed as freestanding structures without any neighboring buildings that may obstruct or occlude natural light. However, this may not always be possible. For example, in some circumstances, it may be necessary to build a greenhouse in the vicinity of, or on top of, a building that may occlude part of the natural light for the greenhouse (e.g., a chimney or tall building or structure). This may be particularly relevant in densely populated regions of the world, or in regions wherein space is otherwise at a premium. By including such neighboring or adjacent structures in the structural model, it can be ensured that the lighting levels in the greenhouse can be accurately modelled.

As described above, the three-dimensional structural model provides a digital representation of a structure and its environment that has substantially the same properties as its real world analogue would have.

In a second step 302, at least one first set of characteristics 434 for the plurality of modelled glass panels 424 and at least one second set of characteristics 436 for the plurality of modelled structural components 426 are determined. Purely for purposes of ease of explanation in the present example, only a single first set of characteristics and a single second set of characteristics will be referred to in the following. It will, however, be understood that, the method steps of the present method are applicable to any suitable or relevant number of first sets or second sets of characteristics.

The first set of characteristics 434 and/or the second set of characteristics 436 may be determined in any suitable manner. In some examples, the first set of characteristics and second set of characteristics are determined in substantially the same manner. In some examples, the first set of characteristics is determined in a different manner than the second set of characteristics.

In some examples, the step of deriving comprises extracting the first set of characteristics 434 from a database (not shown). In some examples, the step of deriving comprises extracting one or more parameters or values from a database and performing one or more operations to determine the first set of characteristics. In some examples, the step of deriving comprises performing one or more modelling steps to derive the first set of characteristics. In some examples, the step of deriving comprises determining the at least one first set of characteristics based on a numerical model. In some examples, the at least one first set of characteristics is derived based on a set of measurement results associated with the at least one glass panel type. It will be appreciated that a number of specific implementations of the step of deriving may be envisaged within the scope of the present disclosure.

Once determined, the first set of characteristics 434 may comprise any suitable parameters, properties or values. In some examples, the first set of characteristics comprises a set of optical parameters corresponding to the parameters of a specific glass panel type. In some examples, the first set of characteristics 434 corresponds to a set of characteristics or parameters associated with the at least one glass panel type 420 of the greenhouse 400. Examples include, without limitation, transmissivity, specular reflectiveness, diffuse reflectiveness or loss.

Similarly, the second set of characteristics 436 may comprise any suitable parameters, properties or values. In some examples, the second set of characteristics comprises a set of optical parameters corresponding to the parameters of the structural components 404 of the greenhouse 400.

In a third step 303, a set of environmental data 438 is provided, the environmental data being associated with the intended geographical location 408 and orientation 410 of the greenhouse 400.

The set of environmental data 438 may comprise any suitable data. In some examples, the set of environmental data comprises weather data. In an example, the set of environmental data comprises historical weather data.

The set of environmental data 438 may be provided in a suitable manner. In some examples, the set of environmental data is provided by a database 440. In some examples, the database is a database of historical weather data.

If the database does not comprise data for the intended geographical location, it may be necessary to perform one or more additional operations in order to provide the set of environmental data. This may, for example, be the case if the above-mentioned database of historical weather data does not comprise data for the intended geographical location but comprises data for locations in the vicinity or within a suitable distance of the intended geographical location.

The step of providing, in some examples, comprises a step 303A of deriving the set of environmental data 438 based on at least one set of source data 442. The source data may, for example, be stored in the database 440. Such derivations may be necessary in cases where the source data does not accurately match one or more aspects of the structural model, such as the intended geographical location. Such a derivation step may be conditional, and may comprise a check to determine whether or not the database comprises suitably matching data. In an example, the database comprises historical weather data for a number of geographical locations. If the database comprises data for the intended geographical location, the data for the intended geographical location is extracted from the database.

In other examples, the step of providing a set of environmental data comprises a step 303B of deriving the set of environmental data based on one or more sets of training data 444. The derivation may be performed in a suitable manner, and using any suitable training data sets. In some examples, such a derivation step is performed by way of a machine learning or neural network algorithm 446. In one such example, the machine learning algorithm is trained on a set of historical weather data for a number of geographical locations. Based on the training data, the machine learning algorithm is used to provide the set of environmental data for the intended geographical location for any specified period of time.

In a fourth step 304, a rendering component 448 is used to determine an irradiance map 450 of the greenhouse based one or more of the 3-dimensional structural model 422, the at least one first 434 or second 436 sets of characteristics, or the set of environmental data 438. The irradiance map, in some examples, comprises irradiance data for a specific point in time (e.g., a certain time and date). In some examples, the irradiance map comprises irradiance data for a defined period of time with a suitable interval (e.g., hourly data for a week). It will be appreciated that any suitable interval and time period may be selected in a suitable manner.

It should be noted that, although referred to as an irradiance map, the map may in some examples comprise additional data. For example, the irradiance map, in some examples, comprises data impacting temperature, humidity, CO₂, or other atmospheric conditions in the greenhouse in addition to the irradiance data. In some examples, the irradiance map additionally or alternatively indicates the suitability for a particular crop or plant, an expected crop yield per unit area or another productivity measure.

Any suitable rendering component may be used. In some examples, the rendering component is a raytracing algorithm. In some examples, the rendering component is a spectral raytracing algorithm. An exemplary spectral raytracing algorithm will be described in more detail in the following.

The rendering step may be carried out in any suitable fashion and using a suitable set of rendering parameters. The choice of rendering parameters may depend on the intended use of the irradiance map.

Although shown in the present example as a single step, the rendering step may be comprised of a number of sub steps. One or more post-rendering processing steps may, for example, be performed in order to aid subsequent processing steps or to facilitate visualization for a user. As an illustrative example, in one rendering sub step, a time integration is performed on the irradiance map for a specified period of time (e.g., a growing season for a specific plant or crop). This may enable a user to easily visualize the time period, which in turn may facilitate the subsequent optimization step.

In a fifth step 305, the irradiance map is optimized based on a set of optimization criteria. Any suitable set of optimization criteria may be used.

The optimization step may be carried out in any suitable manner. In some examples, the optimization step is performed by an optimization element 452. The optimization element may be operated automatically based on the set of optimization criteria. The optimization element may be operated in conjunction with an operator or user.

The above-described example describes a method that enables a user to predict the internal conditions of a specific greenhouse for a specified period of time, and by extension the productivity of the greenhouse for the specified period of time. In turn, this enables a particular design and material choices for a greenhouse to be examined in detail before manufacture begins.

In the preceding example, the invention has been described in general terms. It will be appreciated that a number of exemplary implementations of the method and individual features may be envisaged as part of the present disclosure. Some of these will now be described in more detail. It is to be understood that any of the following exemplary implementations and their features may be combined with any of the other exemplary implementations.

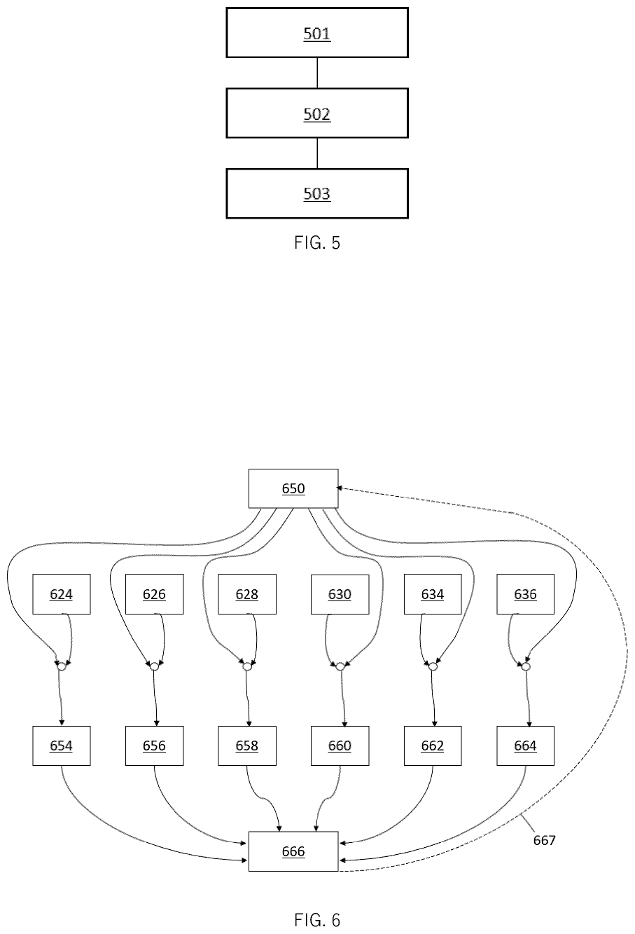

An exemplary optimization step, such as may be implemented in the method described above with reference to FIGS. 3 and 4 will now be described with reference to FIGS. 5 and 6. For ease of comparison with the preceding Figures, elements of FIG. 6 similar to corresponding elements of FIG. 1 or 4 are labelled with reference signs similar to those used in the preceding Figures, but with prefix “6”.

In a first optimizing step 501, one or more of: the plurality of modelled glass panels 624, the plurality of modelled structural components 626, the modelled intended geographical location 628, the modelled intended orientation 630; the at least one first set of characteristics 634; or the at least one second set of characteristics 636 are optimized, the optimization being based on the irradiance map 650 of the greenhouse to determine one or more of: an optimized plurality of modelled glass panels 654, an optimized plurality of modelled structural components 656, an optimized modelled intended geographical location 658, an optimized modelled intended orientation 660; at least one optimized first set of characteristics 662; or at least one optimized second set of characteristics 664.

The optimization may be performed in any suitable manner and using any suitable methodology. It will be appreciated that a number of specific optimization methodologies may be envisaged within the scope of the present disclosure. The optimization may be performed by any suitable component or element, such as the optimization element referred to with reference to FIG. 4 above.

It will be understood that, whilst referred to in their entirety, only a suitable part, portion, sub element or component of any of the above-mentioned elements may be optimized. Purely by way of example, each of the modelled glass panels 624 may, as described above, be comprised of a plurality of parameters, values, sub components or elements. During the optimization step, any or all of such parameters, values, sub components or elements may be optimized. Similarly, where a plurality of elements or components is referred to, it is entirely possible that only a subset or portion of such a plurality is optimized during the optimization step.

In a second optimizing step 502, an optimized irradiance map 666 of the greenhouse is determined based on one or more of: the optimized plurality of modelled glass panels 654, the optimized plurality of modelled structural components 656, the optimized modelled intended geographical location 658, the optimized modelled intended orientation 660; at least one of the optimized first set of characteristics 662, or at least one of the optimized second set of characteristics 664.

The optimized irradiance map 666 may be determined in a suitable manner. In an example, the optimized irradiance map is generated in substantially the same way as the irradiance map 650. Typically, this will result in the optimized irradiance map being directly comparable with the original irradiance map. In other examples, the optimized irradiance map is generated in a different manner. This may allow certain properties of either or both of the original irradiance map or the optimized irradiance map to be highlighted, illustrated or otherwise examined.

In a third optimizing step 503, the steps of optimizing and determining an optimized irradiance map are iteratively repeated until the set of optimization criteria is met (illustrated in FIG. 6 by arrow 667).

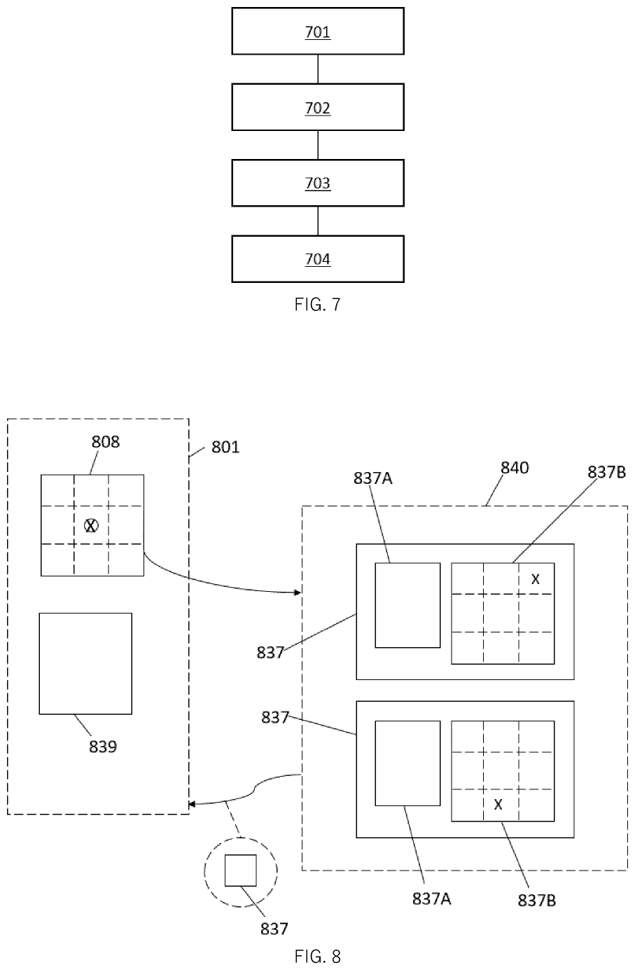

An exemplary step of providing a set of environmental data will now be discussed with reference to FIG. 7 and FIG. 8. For ease of comparison with the preceding Figures, elements of FIG. 8 similar to corresponding elements of FIG. 1, 4 or 6 are labelled with reference signs similar to those used in the preceding Figures, but with prefix “8”.

In a first step 701, a geographical location 808 of the greenhouse is determined at a first entity 801. The determination may be carried out in a suitable manner. In an example, the geographical location is pre-defined (e.g., by a user or operator). In other examples, the geographical location of the greenhouse is determined by way of an algorithm or other operation.

In a second step 702, at least one environmental data entry 837 stored in an environmental database 840 is selected based on the geographical location 808 of the greenhouse. Each of the environmental data entries comprises a set of weather data 837A as well as a geographical location 837B with which the weather data is associated. The selection step may be performed in a suitable manner, and may consist of any number of sub steps.

In some examples, in a first sub step, the geographical location 808 of the greenhouse, or a reference thereto, is transmitted from the first entity to the environmental database in a suitable fashion. It will be appreciated, of course, that this is purely exemplary, and that in some examples, the environmental database 840 or a suitable overview or portion thereof is transmitted to the first entity.

In some examples, in a further sub step, the geographic locational 808 of the greenhouse is compared with the geographical locations 837B of each of the environmental data entries 837 stored in the environmental database. In some instances, there may be a direct match. In such situations, the environmental data entry 837 corresponding to the geographical location 808 of the greenhouse is selected.

In other situations, there is no exact match between the geographic location of the greenhouse and the geographic locations of the environmental data entries in the environmental database. In such a situation, one or more environmental data entries stored in the database are selected according to a suitable parameter. For example, one or more environmental data entries may be selected according to proximity to the geographical location of the greenhouse. In one illustrative example, the two environmental data entries whose geographic locations are closest to the geographic location of the greenhouse are selected.

In a third step 703, one or more environmental data entries are received at the first entity. The environmental data entries may be received in any suitable fashion. In some examples, the one or more environmental data entries are transmitted to the first entity from the environmental database.

In a fourth step 704, a set of weather data 839 for the geographical location 808 of the greenhouse is determined. This determination step may be carried out in a suitable fashion. In the above-mentioned example wherein a match between the geographical location of the greenhouse and the geographic location of an environmental data entry 837 has been determined, weather data from the selected environmental data entry is used.

In another example, wherein two or more environmental data entries 837 have been selected, and wherein no geographical location matches have been found in the environmental database 840, a set of weather data 839 for the geographical location 808 for the greenhouse is derived based on the two or more environmental data entries. This may be performed in a suitable fashion, for example by way of data interpolation.

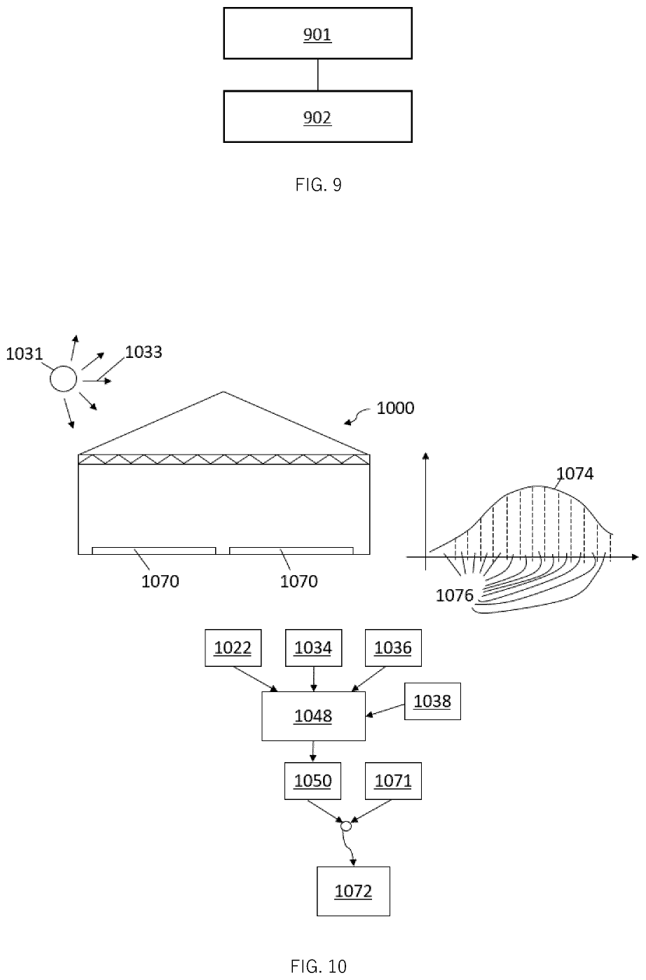

An exemplary step of using a rendering component to determine an irradiance map of the greenhouse will now be described with reference to FIG. 9 and FIG. 10. For ease of comparison with the preceding Figures, elements of FIG. 10 similar to corresponding elements of FIG. 1, 4 or 6 are labelled with reference signs similar to those used in the preceding Figures, but with prefix “10”.

As discussed above, optimization of the light in the greenhouse to a specific crop, or set of crops, enables the highest amount of crops to be cultivated. For example, certain crops require higher light levels than others. Further, in order to maximize production, it is necessary to optimize the spectral composition of the light being used to grow. It is well known that, in order to maximize photosynthesis in a particular crop, the light should be similar to or match the photo response function of the crop. The photo response function is, for purposes of the present invention, defined as the function which maximizes photosynthesis in a plant of the given type.

Further, it is well known that greenhouses may have one or more cultivation areas. Depending on the structure of the greenhouse, and/or the environment surrounding the greenhouse, these cultivation areas may get different amounts of radiation.

In order to model this, in the present example, the modelled greenhouse 1000 comprises one or more modelled cultivation areas 1070 or areas. The modelled cultivation areas are positioned so as to mirror or be substantially analogous to the cultivation areas of the greenhouse to be modelled.

The modelled cultivation areas may be implemented in any suitable fashion. In some examples, the modelled cultivation areas comprise a surface in the modelled greenhouse. In some examples, the modelled cultivation areas comprise one or more crop models. Whilst modelling individual crop plants increasing the resource requirements for carrying out the rendering. However, by modelling individual crop plants, it is possible to model the optical properties of the crop plants, as well as the effect of crop plants on neighboring crop plants. In the present example, the modelled cultivation areas 1070 comprise a spectral photo response function 1071

In a first using step 901, the spectral raytracing algorithm 1048 is used to derive a spectral irradiance map 1050 based on one or more of the 3-dimensional structural model 1022, the at least one first 1034 and second 1036 sets of characteristics, or the set of environmental data 1038. The derivation may be carried out in any suitable fashion. An exemplary derivation step will be discussed in more detail in the following.

The step of deriving may be implemented in any suitable manner and may be based on any suitable characteristics, properties and/or variables. In the present example, the step of using the rendering component to determine the irradiance map is based on the 3-dimensional structural model, the at least one first and second sets of characteristics, and the set of environmental data. It will be appreciated, however that additional and/or alternative parameters, properties or characteristics may be envisaged.

In the present example, the three-dimensional structural model comprises a radiation source 1031 (such as described with reference to FIG. 4 above). The radiation source is modelled such that the emitted modelled radiation 1033 has properties that are similar to radiation emitted by the Sun. In other words, the modelled radiation is intended to closely mimic natural light. In the present example, therefore, the modelled radiation is a radiation spectrum 1074 comprised of a plurality of individual radiation components 1076. Each of the radiation components may contain any suitable portion of the radiation spectrum. In some examples, each of the radiation components comprises a subdivision, portion or part of the radiation spectrum.

It will, of course, be appreciated that the modelled radiation, in some examples, is modified or altered by one or more of the first set of characteristics 1034, the second set of characteristics 1036 or the set of environmental data 1038. Purely for exemplary purposes, if the environmental data comprises data that models overcast or foggy weather, the modelled radiation may be modified appropriately.

The spectral irradiance map 1050, when derived, may have any suitable sets of properties and may comprise any suitable data or information. In the present example, the spectral irradiance map comprises a plurality of sub-maps (not shown), each of which comprises an irradiance map for one of the plurality of radiation components 1076 of the radiation spectrum 1074.

In a second using step 902, a spectral response 1072 of a modelled crop element is derived based on the spectral irradiance map 1050 and the spectral photo response function 1071. The spectral response may be derived in any suitable fashion using any suitable methodology or algorithm. An exemplary methodology will be described in more detail in the following. It will, however, be appreciated that a number of specific implementations may be envisaged by the skilled person.

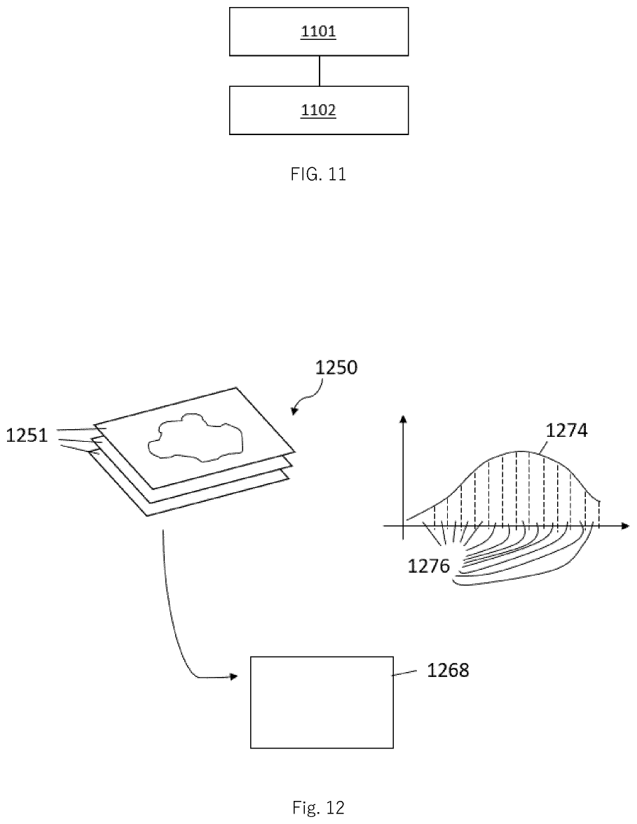

An exemplary step of deriving a spectral response of the modelled crop element will now be discussed with reference to FIG. 11 and FIG. 12. This exemplary step may be implemented in any of the methods discussed with reference to the Figures above. For ease of comparison with the preceding Figures, elements of FIG. 12 similar to corresponding elements of preceding Figures are labelled with reference signs similar to those used in these preceding Figures, but with prefix “12”.

In the present example, the spectral irradiance map 1250 comprises plurality of sub-maps 1251, each of said sub-maps being associated with a radiation component 1274 of a radiation spectrum 1274 emitted by a modelled radiation source (not shown).

In a first deriving step 1101, a spectral response 1268 is determined for a radiation component 1276 of the first plurality of radiation components. Each radiation component is associated with a wavelength range within the emission spectrum of a radiation source, such as the Sun. This derivation step may be carried out in any suitable fashion. In some examples, the derivation step is performed in a manner similar to that described with reference to the preceding Figures.

In a second deriving step 1102, the step of determining is repeated for each radiation component 1276 of the first plurality of radiation components.

Once the spectral response of the modelled crop element has been determined, one or more additional operations or steps may be carried out. In some cases, these additional operations or steps are performed as part of the derivation step. In other cases, the additional operations or steps are performed as part of the optimization step.

In the above, methods and systems have been described in isolation. However, in some circumstances, the above methods and systems may interact with one or more further systems and may perform one or more further method steps during such interactions.

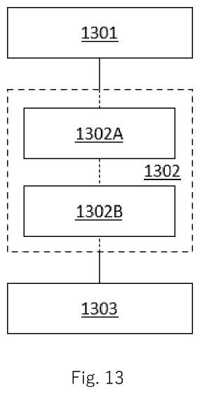

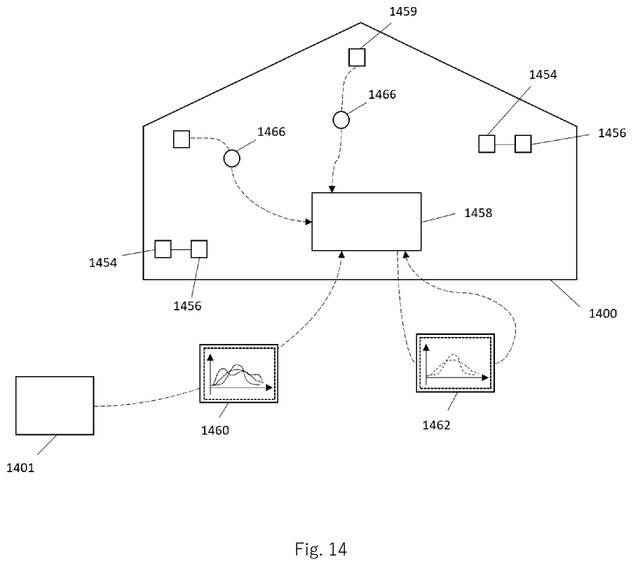

One such example will now be described with reference to FIG. 13 and FIG. 14. For ease of comparison with the preceding Figures, elements of FIG. 14 similar to corresponding elements of preceding Figures are labelled with reference signs similar to those used in these preceding Figures, but with prefix “14”.

A greenhouse 1400, such as the one described in previous examples, is used for growing crops. In order to control the climate inside the greenhouse, the greenhouse is provided with a number of climate control units 1454, each of which controls one or more climate control elements 1456. Examples of climate control elements include, without limitation: shades that can be opened to shield the interior of the greenhouse from sunlight; windows that can be opened to admit air; misting devices; humidifiers; dehumidifiers; CO₂ controllers; or lighting fixtures. In some examples, the climate control units are controlled by a greenhouse control unit 1458. The greenhouse control unit may be a central terminal located in the greenhouse, or it may be a software application run on a computing or mobile device that is connected to the climate control units via a suitable connection.

The greenhouse also comprises a number of climate sensors 1459, such as thermometers, hydrometers, CO₂ sensors, barometers, and the like. The climate sensors may in some examples be connected to the greenhouse control unit, such that a user can perform sensor readings centrally.

In known greenhouses, climate elements are typically controlled manually. A user has access to the output from the climate sensors and based on this data, as well as the user's knowledge, the various climate control elements can be controlled so as to take into account different circumstances. For example, if the light levels are too high, the user can lower the shades. If the temperature is too high, windows can be opened. As described above, however, in such examples, the operation of the greenhouse is entirely reliant on the user, which can easily lead to a reduction in productivity due to non-ideal climate circumstances.

As an example, a user may notice that the temperature in the greenhouse is above the ideal temperature due to unexpectedly high levels of sunlight, e.g., if a day has been previously overcast and the cloud cover has suddenly broken. The user may therefore open the shading screens in the greenhouse to reduce the temperature. However, at the point in time where the shading screens are opened, due to the low speed of the screen drivers and large area of the screens, the temperature has already risen and may take a significant amount of time to reduce to the ideal level. During this time, the plants or crops in the greenhouse will be less productive due to the excessive heat.

In some known greenhouses, the greenhouse control unit 1458 is provided with means for automatic control of at least some of the climate control units 1454. In such known greenhouses, the greenhouse control unit may be provided with one or more applications that enable a user to specify one or more control profiles, such as schedules for shading screens, misting or lighting fixture control. Whilst this eases the burden on the user, it essentially suffers from the same problem of the entirely manual situation, i.e., the settings are reliant on the user's knowledge which may lead to a reduction in productivity.

In some known greenhouses, the greenhouse control unit 1458 may be in communication with an internal or external processing unit. Sensor data received by the greenhouse control unit may be transmitted to the processing unit, which determines a current climate profile that is returned to the greenhouse control unit. Based on the current climate profile, the greenhouse control unit can generate a control file for each of the climate control units. However, whilst such systems can take into account changes in the environment (e.g., a change in the weather), they do not provide any predictive capabilities. This means that there inevitably is a delay between a change in the environment and the compensating changes happening in the greenhouse. As described above, such delays (e.g., the above-mentioned scenario of excessive heat in the greenhouse) will lead to a reduction in productivity, and may even lead to crop or plant damage.

In a first step 1301, a predicted climate profile 1460 for a prediction period is received by the greenhouse control unit 1458 from a computing system 1401. The computing system is substantially identical to those performing any one of the methods described in the preceding embodiments.

The computing system may generate the predicted climate profile in any suitable fashion. The predicted climate profile may comprise any suitable climate data. In some examples, the predicted climate profile comprises one or more of the features of the optimized irradiance map 1452 described in the above examples. For example, the predicted climate profile comprises predicted temperatures for the greenhouse, predicted humidity and predicted radiation levels. In other terms, the predicted climate profile comprises data about the predicted conditions in the greenhouse based on the predicted environmental circumstances (e.g., the weather).

The predicted climate profile may cover any suitable prediction period. In an example, the prediction period is 24 hours. In other examples, the prediction period is one of 6, 12, 36, 48 or 60 hours.

In a second step 1302, a climate control profile 1462 is generated based on the predicted climate profile, the climate control profile comprising climate control data 1464 for the one or more climate control units.

The climate control profile 1462 may be generated in any suitable fashion and may comprise any suitable data or information. In some examples, the climate control profile comprises a schedule for the one or more climate control elements 1456 that is usable by the one or more climate control units 1454. For example, a climate control profile may contain a schedule for operating shading screens and/or windows located in the greenhouse that takes into account the predicted conditions. For example, if it is predicted that the temperature is to rise suddenly due to high levels of sunshine during a particular afternoon, the climate control profile contains instructions for shading screens and windows to be opened in advance of this event. In this manner, it can be ensured that the ideal environmental conditions are maintained inside the greenhouse despite the changes in outside conditions.

It will be appreciated that a number of methodologies and mechanisms for generating the climate control profile may be envisaged. Purely for exemplary purposes, and without limitation, an exemplary generating step will briefly be described.

In a first generating step 1302A, one or more measured environment parameters 1466 are received from the or more climate sensors 1459 located in the greenhouse. These parameters may be received in any suitable manner and with a suitable frequency. In some examples, the parameters are received continually. In other examples, parameters are only received on request from the greenhouse control unit 1458.

In a second generating step 1302B, the received measured environment parameters 1466 are compared with the predicted climate profile 1460. This comparison is performed to verify or validate the predicted climate profile, and to determine any deviation therefrom that needs to be taken into account in subsequent steps.

In a third generating step 1302C, the climate control profile 1462 is derived based on the received environment parameters and the predicted climate profile. The derivation may be performed in any suitable fashion and using a suitable methodology. This will typically involve deriving a climate control setting for a particular climate control element that enables the desired conditions inside the greenhouse to be maintained in view of the predicted climate profile. It will be appreciated that the implementation of such is dependent on the specific features and properties of the individual greenhouse, and that a number of such implementations may be envisaged by a suitably skilled person.

In a third step 1303, the climate control data 1464 is transmitted to the climate control units 1454. In turn, the climate control units generate instructions to the climate control elements 1456.

It will be appreciated that, whilst described as a linear process in the above, the control methodology, or the individual steps thereof, may be implemented as a periodically recurring method. For example, the comparison step described above may be performed periodically so as to continually validate the accuracy of the predicted climate profile, in turn ensuring that the climate control profile is updated whenever necessary.

It will be understood that various modifications and/or improvements obvious to the person skilled in the art may be made to the various embodiments of the invention described in the present description without departing from the scope of the invention defined by the appended claims.

1. A method for modelling irradiance levels in a solar light type glass greenhouse, the greenhouse comprising a plurality of glass panels having at least one glass panel type, and the greenhouse having an intended geographical location and intended orientation, the method comprising:
providing a three-dimensional structural model of the greenhouse, the structural model comprising: a plurality of modelled glass panels, a plurality of modelled structural components, a modelled intended geographical location, and a modelled intended orientation;
determining at least a first set of characteristics for the plurality of modelled glass panels and at least a second set of characteristics for the plurality of modelled structural components;
providing a set of environmental data, the environmental data being associated with the intended geographical location and orientation;
using a rendering component to determine an irradiance map of the greenhouse based on the 3-dimensional structural model, the at least one first and second sets of characteristics, and the set of environmental data; and
optimizing the irradiance maps based on a set of optimization criteria.

2. The method according to claim 1, wherein the optimizing further comprises:
optimizing one or more of: the plurality of modelled glass panels, the plurality of modelled structural components, the modelled intended geographical location, the modelled intended orientation; the at least one first set of characteristics, or the at least one second set of characteristics, the optimization being based on the irradiance map of the greenhouse to determine one or more of: an optimized plurality of modelled glass panels, an optimized plurality of modelled structural components, an optimized modelled intended geographical location, an optimized modelled intended orientation; at least one optimized first set of characteristics, or at least one optimized second set of characteristics;
determining an optimized irradiance map of the greenhouse based on one or more of: an optimized plurality of modelled glass panels, an optimized plurality of modelled structural components, an optimized modelled intended geographical location, an optimized modelled intended orientation; at least one optimized first set of characteristics, or at least one optimized second set of characteristics; and
iteratively repeating the optimizing and determining an optimized irradiance map until the set of optimization criteria is met.

3. The method according to claim 1, wherein the set of environmental data comprises statistical meteorological data for the intended geographical location.

4. The method according to claim 1, wherein the providing a set of environmental data further comprises:
providing environmental data for at least one geographical location.

5. The method according to claim 1, wherein the at least one first set of characteristics corresponds to a set of characteristics associated with the at least one glass panel type.

6. The method according to claim 5, wherein the determining at least a first set of characteristics further comprises: extracting the at least one first set of characteristics from a database; deriving the at least one first set of characteristics based on a numerical model; or deriving the at least one first set of characteristics based on a set of measurement results associated with the at least one glass panel type.

7. The method according to claim 5, wherein the determining at least a first set of characteristics further comprises determining a plurality of first sets of characteristics, each of the first sets of characteristics corresponding to a set of characteristics associated with a respective one of a plurality of glass panel types.

8. The method according to claim 1, wherein the rendering component is a spectral raytracing algorithm.

9. The method according to claim 8, wherein the spectral raytracing algorithm comprises at least one spectral photo response function for at least one crop intended for cultivation in the greenhouse.

10. The method according to claim 9, wherein the using the rendering component comprises using the spectral raytracing algorithm to derive a spectral irradiance map based on one or more of the 3-dimensional structural model, the at least one first and second sets of characteristics, and the set of environmental data.

11. The method according to claim 10, further comprising a deriving a spectral response of a modelled crop element based on the spectral irradiance map and the spectral photo response function.

12. The method according to claim 11, wherein the spectral irradiance map comprises a first radiation spectrum, the first radiation spectrum having a first plurality of radiation components, wherein
the deriving a spectral response of the modelled crop element further comprises:
determining a spectral response for a radiation component of the first plurality; and
repeating the determining step for each radiation component of the first plurality.

13. The method according to claim 1, further comprising:
generating a predicted climate profile for a prediction period based on the optimized irradiance map;
transmitting the climate profile to a greenhouse control unit, wherein the greenhouse control unit is operable to use the predicted climate profile to control one or more climate control units, each climate control unit operable to control one or more climate elements of a greenhouse.

14. A method for operating a greenhouse control unit in a greenhouse, the greenhouse comprising one or more climate control units operable to control one of a plurality of environment parameters and one or more climate sensors, the method comprising:
receiving a predicted climate profile;
generating a climate control profile based on the predicted climate profile, the climate control profile comprising climate control data for the one or more climate control units; and
transmitting the climate control data to the one or more climate control units.

15. The method according to claim 14, the method further comprising:
receiving one or more measured environment parameters from the or more climate sensors; and
comparing the received measured environment parameters with the predicted climate profile, wherein
the generating the climate control profile is based on the comparison between the received measured environment parameters and the predicted climate profile.

16. The method according to claim 15, the method further comprising:
updating the generated climate control profile based on subsequently received measured environment parameters.

17. A computer program comprising instructions which, when the program is executed by a computer, cause the computer to carry out the method of claim 1.

18. A computer readable medium including program instructions which, when executed by a computer, cause the computer to carry out the method of claim 1.

19. A computer system, the computer system comprising a processing unit, wherein the computer system is operable to carry out the method of claim 1.
